(19) United States
(12) Patent Application Publication
(10) Pub. No.: US 2010/0230792 A1
(43) Pub. Date: Sep. 16, 2010

(54) Premolded Substrates with Apertures for Semiconductor Die Packages with Stacked Dice, Said Packages, and Methods of Making the Same

(76) Inventors: Scott Irving, Cape Elizabeth, ME (US); Yong Liu, Scarborough, ME (US); Yumin Liu, Suzhou (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/403,294

(22) Filed: Mar. 12, 2009

(51) Int. Cl. H01L 23/495; H01L 25/11; H01L 21/56

(52) U.S. Cl. 257/676; 257/686; 264/272.17; 257/E23.031; 257/E25.027

(57) ABSTRACT

Disclosed are premolded substrates for semiconductor die packages and methods of making such substrates. An exemplary premolded substrate comprises a leadframe having a first surface, a second surface, a central portion disposed between the first and second surfaces, and a plurality of electrically conductive leads disposed about the central portion; a body of electrically insulating material disposed in a portion of the central portion of the leadframe and between the leads of the leadframe; and an aperture disposed in the leadframe's central portion and between the leadframe's first and second surfaces.

### CROSS-REFERENCES TO RELATED APPLICATIONS

NOT APPLICABLE

### BACKGROUND OF THE INVENTION

Personal portable electronic products, such as cell phones, personal data assistants, digital cameras, laptops, etc., are generally comprised of several packaged semiconductor IC chips and surface mount components assembled onto interconnect substrates, such as printed circuit boards and flex substrates. There is an ever increasing demand to incorporate more functionality and features into personal portable electronic products, while at the same time shrink the sizes of such devices. This, in turn, has placed ever increasing demands on the design, size, and assembly of the interconnect substrates. As the number of assembled components increases, substrate areas and costs increase, while demand for a smaller form factor increases.

In another area, there is an ever increasing demand to reduce the size of switching power converters that are for computers, laptops, and portable electronic devices. These power supplies often bridge between two electrically isolated power circuits where control information is optically communicated between the circuits by one or more optocouplers. Such optocouplers are bulky because of the need to arrange two dice to be in optical communication with one another, and to optically isolate the dice from external light sources.

### BRIEF SUMMARY OF THE INVENTION

As part of making their invention, the inventors have recognized that there is a need to address the above issues and that it would be advantageous to find ways to enable increases in functionality and performance of electronic products without causing increases in substrate areas and costs, and decreases in product yields. As also part of making their invention, the inventors have recognized that many electronic products have several electrical components, particularly semiconductor dice, that can be grouped together in several small groups that provide specific functions. As also part of making their invention, the inventors have discovered that creating premolded leadframes with apertures preformed therein to accept one or more dice can be used to house stacked dice in a compact arrangement that is well adapted for use in a wide variety of package formats. The inventors have further discovered that stacking the optoelectronic dice of an optocoupler on opposite ends of an aperture formed in a premolded leadframe can significantly reduce the area and volume of the optocoupler.

Accordingly, a first general exemplary embodiment according to the invention is directed to a premolded substrate for semiconductor die packages, the premolded substrate comprising: a leadframe having a first surface, a second surface, a central portion disposed between the first and second surfaces, and a plurality of electrically conductive leads disposed about the central portion; a body of electrically insulating material disposed in a portion of the central portion of the leadframe and between the leads of the leadframe; and an aperture disposed in the leadframe's central portion and between the leadframe's first and second surfaces.

With this construction, a small area die may be flip-chip bonded to the active surface of a large area die, and the large area die may in turn be flip-chip bonded to the leads of a premolded substrate according the present invention, with the small area die being disposed within the aperture of the premolded substrate, thereby packaging two dice essentially within space normally used to package one die. In general, a premolded substrate may have many apertures, and many die may be housed by the apertures, with two or more dice disposed over and in each aperture. Also with this construction, a receiver die and transmitter die of an optocoupler may be disposed on opposite ends of an aperture formed in premolded substrate, with each die being wider than at least one dimension of the aperture's end. Leads of the leadframe may have portions that extend adjacent to, or abut, the aperture, and each die may be disposed over an end of the aperture and be flip-chip bonded to the adjacent and/or abutting lead portions. With this construction, light from the transmitter may be counter to the receiver through the aperture, and a compact arrangement of dice may be achieved compared to the conventional approach of disposing the die in a horizontal arrangement of a substrate with optical gel disposed over and between the dice. Multiple optocouplers may be integrated within a single package and on a premolded substrate having multiple apertures (with as little as one aperture per optocoupler dice set).

A second general exemplary embodiment according to the invention is directed to a method of making a premolded substrate for semiconductor die packages, the method broadly comprising forming a body of molding material between the surfaces of a leadframe with an aperture passing between the surfaces of the leadframe, the body of molding material being formed prior to attaching an electrical component to the leadframe. The aperture in the body of molding material may be formed by a mold cavity block with a protrusion that forms the aperture during the molding process and before the molding material solidifies. The aperture may also be formed by removing a portion of the formed molding body after the molding material has solidified, such as by stamp cutting.

The present invention also encompasses packages that include premolded substrates according to the present invention, such as the examples provided above.

The above general embodiments and other embodiments of the invention are described in the Detailed Description with reference to the Figures. In the Figures, like numerals may reference like elements and descriptions of some elements may not be repeated.

### BRIEF DESCRIPTION OF THE DRAWINGS

FIG. 1 shows a top view of an exemplary embodiment of a premolded substrate for component packages according to the present invention.

FIG. 2 shows a side view of the exemplary embodiment shown in FIG. 1 according to the present invention.

FIG. 3 shows a side view of an exemplary package that uses an exemplary premolded substrate according to the present invention.

FIG. 4 shows a top view of another exemplary embodiment of a premolded substrate for component packages according to the present invention.

FIGS. 5-6 shows top and bottom views, respectively, of another exemplary premolded substrate suitable for optocoupler applications according to the present invention.

FIGS. 7-9 show partial-transparent top, bottom, and side perspective views, respectively, of an exemplary optical package that uses an exemplary premolded substrate according to the present invention.

FIGS. 10-15 illustrate aspects of exemplary method embodiments of making premolded substrates according to the present invention.

### DETAILED DESCRIPTION OF THE INVENTION

The present invention will be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to one skilled in the art. In the drawings, the thicknesses of layers and regions may be exaggerated for clarity. The same reference numerals are used to denote the same elements throughout the specification. The elements may have different interrelationships and different positions for different embodiments.

It will also be understood that when a layer is referred to as being “on” another layer or substrate, it can be directly on the other layer or substrate, or intervening layers may also be present. It will also be understood that when an element, such as a layer, a region, or a substrate, is referred to as being “on,” “connected to,” “electrically connected to,” “coupled to,” or “electrically coupled to” another element, it may be directly on, connected or coupled to the other element, or one or more intervening elements may be present. In contrast, when an element is referred to as being “directly on,” “directly connected to” or “directly coupled to” another element, there are no intervening elements or layers present. In cases where a figure shows an embodiment where one element is “directly on,” “directly connected to” or “directly coupled to” another element, it may be appreciated that a claim of an application may be amended to recite that the element is “directly on,” “directly connected to” or “directly coupled to” the other element. The term “and/or” used herein includes any and all combinations of one or more of the associated listed items.

The terms used herein are for illustrative purposes of the present invention only and should not be construed to limit the meaning or the scope of the present invention. As used in this specification, a singular form may, unless definitely indicating a particular case in terms of the context, include a plural form. Also, the expressions “comprise” and/or “comprising” used in this specification neither define the mentioned shapes, numbers, steps, actions, operations, members, elements, and/or groups of these, nor exclude the presence or addition of one or more other different shapes, numbers, steps, operations, members, elements, and/or groups of these, or addition of these. Spatially relative terms, such as “top,” “over,” “above,” “upper,” “bottom,” “under,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device (e.g., substrate, package) in use or operation in addition to the orientation depicted in the figures. For example, if the device in the figures is turned over, elements described as “below” or “beneath” or “under” other elements or features would then be oriented “over” or “above” the other elements or features. Thus, the exemplary term “above” may encompass both an above and below orientation.

As used herein, terms such as “first,” “second,” etc. are used to describe various members, components, regions, layers, and/or portions. However, it is obvious that the members, components, regions, layers, and/or portions should not be defined by these terms. The terms are used only for distinguishing one member, component, region, layer, or portion from another member, component, region, layer, or portion. Thus, a first member, component, region, layer, or portion which will be described may also refer to a second member, component, region, layer, or portion, without departing from the scope of the present invention.

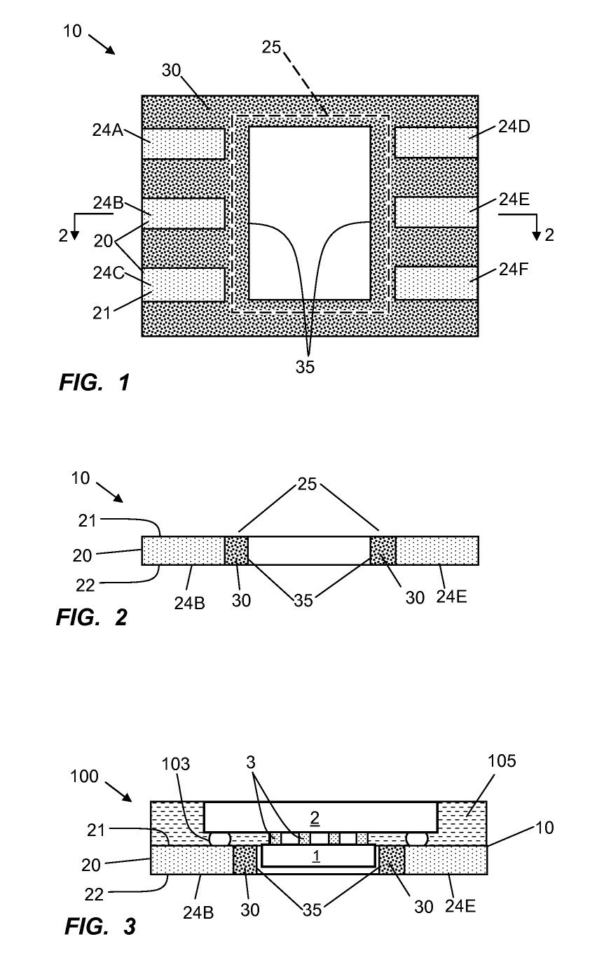

FIG. 1 shows a top plan view of an exemplary embodiment 10 of a premolded substrate for component packages, such as semiconductor dice packages, according to the present invention; and FIG. 2 shows a side view thereof taken along the cut lines 2-2 shown in FIG. 1. Referring to both FIGS. 1 and 2, premolded substrate 10 comprises a leadframe 20 having a first surface 21, a second surface 22, a central portion 25, and a plurality of electrically conductive leads 24A-24F disposed about the central portion. Leadframe 20 may have a thickness in the range of 50 microns to 500 microns, with a range of 100 microns to 250 microns being more typical, and may comprise a core layer of copper that is coated with layers of one or more metals, such as nickel, that better resist oxidation. Premolded substrate 10 further comprises a body 30 of electrically insulating material disposed in a portion of the leadframe's central portion 25 between the leadframe's leads 24A-24F. Body 30 may comprise epoxy molding material, polyimide, silicone, and the like, and is preferably molded to be flush with the leadframe's surfaces 21-22. Premolded substrate 10 further comprises an aperture 35 disposed in the leadframe's central portion and between the leadframe's first and second surfaces, and surrounded by body 30 of molding material. Aperture 35 may be dimensioned to accept one or more semiconductor dice, with typical minimum dimensions being about 0.5 mm on a side, and typical maximum dimensions being the size of the largest semiconductor die (2.5 cm on a side at present).

FIG. 3 shows a side view of a first exemplary package embodiment 100 using premolded substrate 10 and two semiconductor dice 1 and 2 that are attached and electrically coupled to one another by a set of conductive interconnects 3, which may comprise solder, silver paste, metal-filled epoxy, other conductive adhesives, ultrasonically bonded metal (non-solder) posts or wires, and the like. The active surface of die 1 faces a surface of die 2, such as the active surface of die 2, and is smaller than die 2. Die 1 has interconnect pads that are electrically coupled to interconnect pads of die 2 by interconnect bumps (flip-chip bonded), ultrasonic bonds, silver paste, metal-filled epoxy, other conductive adhesives, or the like. In turn, die 2 is attached and electrically coupled to the leads 24A-24F of leadframe 20 by conductive interconnects 103, which may comprise solder, silver paste, metal-filled epoxy, other conductive adhesives, ultrasonically bonded metal (non-solder) posts or wires, and the like. Die 2 may be constructed with interconnect pads and traces on its surfaces that electrically couple one or more electrodes of die 1 to one or more leads 24A-24F by way of one or more conductive interconnects 103, and that electrically couple one or more electrodes of die 1 to one or more electrodes of die 2. In one implementation, die 2 may comprise a semiconductor power device, and die 1 may comprise control circuitry for the power device. In another implementation, one of the dice may comprise analog circuitry and the other may comprise digital circuitry. A body 105 of electrically insulating molding material may be formed over the top surface 21 of premolded substrate 20 and around die 2. The back surface of die 2 may be left exposed in the case that an electrode is present at its back surface, and/or to allow a heat sinking element to be attached to it.

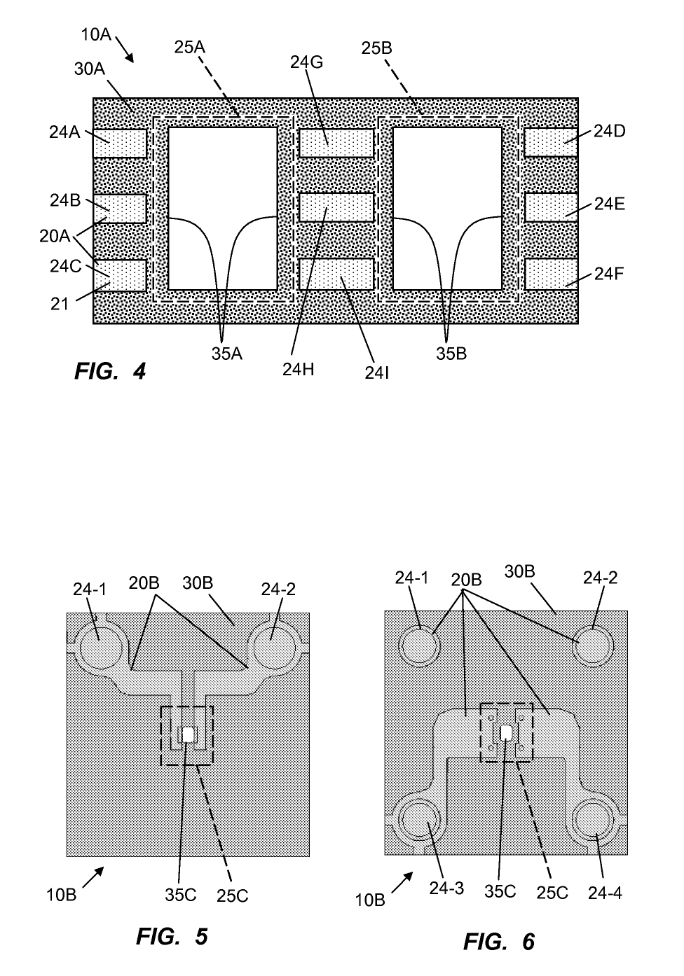

FIG. 4 shows a top plan view of a second exemplary embodiment 10A of a premolded substrate for component packages, such as semiconductor dice packages, which has two apertures 35A and 35B according to the present invention. Premolded substrate 10A comprises a leadframe 20A having a first surface 21, a second surface (not shown) opposite to first surface 21, two central portions 25A and 25B, and a plurality of electrically conductive leads 24A-24I disposed about the central portions. Leadframe 20A may have a thickness in the range of 50 microns to 500 microns (more typically in the range of 100 microns to 250 microns), and may comprise a core layer of copper that is coated with layers of one or more metals, such as nickel, that better resist oxidation. Premolded substrate 10A further comprises a body 30A of electrically insulating material disposed about the leadframe's central portions 25A and 25B amongst the leadframe's leads 24A-24I, as shown in the figure. Body 30A may comprise epoxy molding material, polyimide, silicone, and the like, and is preferably molded to be flush with the leadframe's surfaces 21-22. Premolded substrate 10A further comprises apertures 35A and 35B disposed in the leadframe's central portions 25A and 25B, respectively, and between the leadframe's first and second surfaces. Each aperture 35A and 35B is surrounded by body 30A of molding material. Each aperture 35A and 35B is dimensioned to accept one or more semiconductor dice, with typical minimum and maximum dimensions being those indicated above for premolded substrate 10. Leads 24G-24I are disposed between apertures 35A and 35B, and may be used to electrically interconnect semiconductor dice that are disposed within the apertures (that is, a die that is disposed in or over aperture 35A may be interconnected to a die that is disposed in or over aperture 35B by way of leads 24G-24I).

Premolded substrates according to the present invention may be used to house the optoelectric dice of optocouplers with improved optical coupling and isolation compared to prior art approaches. FIG. 5 shows a top plan view of an exemplary premolded substrate 10B suitable for optocoupler applications, and FIG. 6 shows a bottom plan view thereof. Referring to both FIGS. 5 and 6, premolded substrate 10B comprises a leadframe 20B having a top surface (FIG. 5) and a bottom surface (FIG. 6), a central portion 25C disposed between the top and bottom surfaces, and a plurality of electrically conductive leads 24-1 through 24-4 disposed about the central portion. Leadframe 20B may have a thickness in the range of 50 microns to 500 microns, with a range of 100 microns to 250 microns being typical, and may comprise a core layer of copper that is coated with layers of one or more metals, such as nickel, that better resist oxidation. Premolded substrate 10B further comprises a body 30B of electrically insulating material disposed in a portion of the leadframe's central portion 25C between the leadframe's leads 24-1 through 24-4. Body 30B may comprise epoxy molding material, polyimide, silicone, and the like, and is preferably molded to be flush with the leadframe's top and bottom surfaces. Premolded substrate 10B further comprises an aperture 35C disposed in the leadframe's central portion 25C and between the leadframe's top and bottom. Aperture 35C is dimensioned to be smaller than the opto-electronic components so that opto-electric dice may be disposed over the open faces of aperture 35C (as illustrated further below). At the top surface (FIG. 5) of premolded substrate 10B, lead 24-1 and 24-2 have interior ends that abut respective portions (e.g., sides) of the perimeter of aperture 35C. At the bottom surface (FIG. 6) of premolded substrate 10B, lead 24-3 and 24-4 have interior ends that lie adjacent to respective portions (e.g., sides) of the perimeter of aperture 35C. The interior ends of leads 24-1 through 24-4 have thicknesses that are less than half the thickness of the leadframe so that the interior ends of leads 24-1 and 24-2 can overlap interior ends of leads 24-3 and 24-4 around aperture 35C without physically touching.

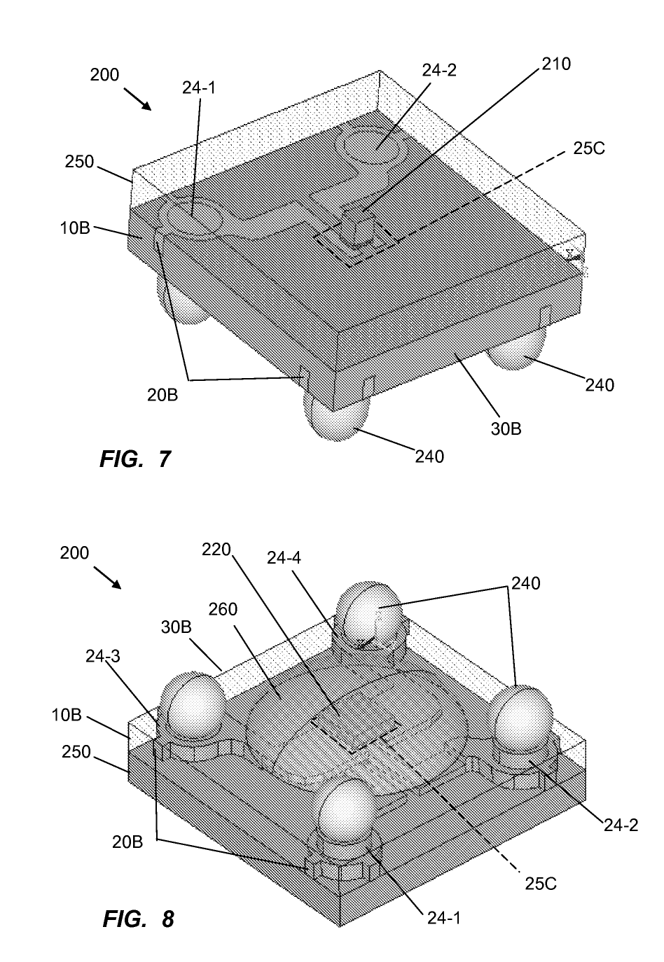

FIG. 7 shows a partial-transparent top perspective view of an exemplary optical package 200 that uses to premolded substrate 10B to house an optoelectronic transmitter die 210 and an optoelectronic receiver die 220 (shown in FIG. 8). As can be seen in the figure, the top surface (e.g., active surface) of transmitter die 210 is disposed in the middle of the leadframe's central portion 25C, and is placed over the top open face of aperture 35C, and has two electrodes that are electrically coupled to leads 24-1 and 24-2. The leads may be coupled to the die electrodes by ultrasonic bonding, or by a conductive adhesive such as solder, silver paste, or the like. Transmitter die 210 may comprise a vertical light emitting device, such as a vertical-cavity surface-emitting laser (VCSEL), which directs light into aperture 35C. A body 250 of molding material, shown in transparent outline, may be disposed over transmitter die 210 and the top surface of premolded substrate 10B to protect transmitter die 210 and to provide optical isolation (e.g., body 250 may comprise an optically opaque material). Conductive interconnect bumps 240 are disposed on the outer portions of leads 24-1 through 24-4, as best shown in FIG. 8.

FIG. 8 shows a partial-transparent bottom perspective view of optical package 200, where the body 30B of molding material is shown in transparent outline. As can be seen in the figure, the top surface (i.e., active surface) of receiver die 220 is disposed in the middle of the leadframe's central portion 25C, and is placed over the top open face of aperture 35C, and has two electrodes that are electrically coupled to leads 24-3 and 24-4. The leads may be coupled to the die electrodes by ultrasonic bonding, or by a conductive adhesive such as solder, silver paste, or the like. Receiver die 220 may comprise a planar photodiode, which receives light at its top surface from transmitter die 210 through aperture 35C. A body 260 of molding material or sealant, shown in transparent outline in the figure, may be disposed over receiver die 220 and a portion of the bottom surface of premolded substrate 10B to protect receiver die 220 from corrosion and to provide optical isolation (e.g., body 260 may comprise an optically opaque material). Conductive interconnect bumps 240 are disposed on the distal ends of leads 24-1 through 24-4, and have heights that extend above the height of body 260.

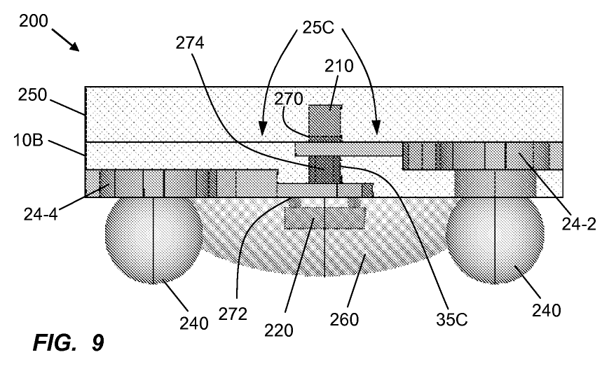

FIG. 9 shows a transparent side view of package 200, showing aperture 35C, and showing how the interior portions of leads 24-2 and 24-4 are separated from one another in the central portion 25C. Dice 210 and 220 may be attached to the leads with conductive bodies 270 and 272, respectively, which may comprise solder. Optically transparent coupling gel 274 may be disposed in aperture 35C, but is not necessary.

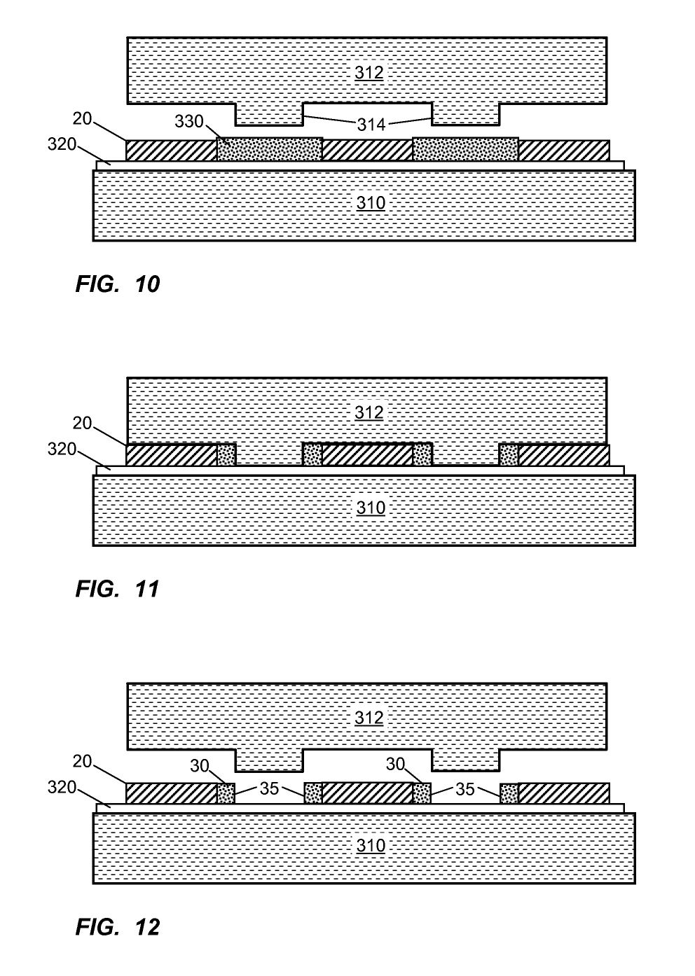

FIGS. 10-15 illustrate exemplary embodiments of making premolded substrates for semiconductor die packages according to the present invention. An exemplary method broadly comprises forming a body of molding material between the surfaces of a leadframe with at least one aperture passing between the surfaces of the leadframe, and disposed adjacent to the interior portions of a plurality of the leadframe's leads. The body of molding material is formed prior to attaching any electrical components to the leadframe, which is contrary to the conventional leadframe formation process where the electrical components are attached to the leadframe before the molding material is formed over the leadframe. The aperture in the body of molding material may be formed by a mold cavity block with a protrusion that forms the aperture during the molding process and before the molding material solidifies. This is illustrated by the sequence of actions shown in FIGS. 10-12, where a reel of leadframes 20 is passed through a molding machine having a top cavity block 312 with protrusions 314 and a flat bottom cavity block 310. Prior to molding, a carrier film 320 is attached to one side of the leadframe reel; it serves to prevent the molding material from contacting the bottom cavity block 310. As shown in FIG. 10, liquid molding material 330 is disposed over the top surface of the leadframes 20, without the presence of electrical components at the top surface of the leadframe. The molding material may comprise a material that becomes a liquid when heated to a temperature above room temperature, and turns back into a solid when cooled back to room temperature (e.g., a thermoplastic material). It may also comprise a liquid material that is converted to a solid by exposure to heat, by exposure to ultraviolet light, and/or by a chemical reaction within the material (e.g., a thermosetting material). As shown in FIG. 11, top cavity block 312 and bottom cavity block 310 are brought together such that protrusions 314 penetrate through the liquid molding material 330 and contact carrier film 320, which form corresponding apertures. Excess liquid molding material is squeezed out of the sides of leadframes; and the molding material is allowed to cool and solidify. As shown in FIG. 12, the cavity blocks 310 and 312 are retracted from one another to provide the premolded substrate with an aperture so dimensioned to accept one or more semiconductor dice. The top cavity block 312 may be coated with a material layer that does not adhere to the solidified molding material. Any excess molding flash may be cut away from the aperture, if needed, or pulled off when carrier film 320 is separated from the leadframe 20. To prevent such flash material from initially forming, cavity blocks 310 and 312 may be first brought together to cause protrusions 314 to contact carrier film 320, and liquid molding material may then be injected into the empty gaps between the protrusions and the leadframe.

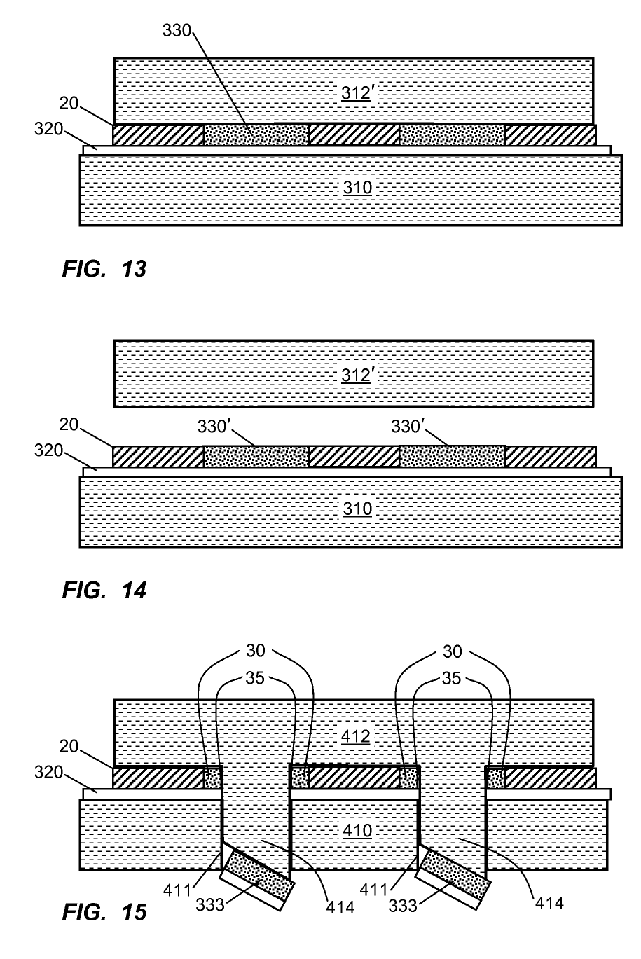

FIGS. 13-15 illustrate method embodiments where the aperture is formed by removing a portion of solidified molding material from a premolded substrate. As illustrated in FIG. 13, a reel of leadframes 20 disposed on a carrier film 320 is passed through a molding machine having a flat top cavity block 312′ (without protrusions) and a flat bottom cavity block 310. Liquid molding material 330 is disposed over the top surface of the leadframes 20, and the top cavity block 312′ and bottom cavity block 310 are brought together such that top cavity block 312′ contacts the tops of the leadframes 20. Excess molding material is squeezed out of the sides of leadframes, and the molding material is allowed to solidify without the presence of electrical components on the top surface of the leadframe. The molding material may comprise a material that becomes a liquid when heated to a temperature above room temperature, and turns back into a solid when cooled back to room temperature (e.g., a thermoplastic material). It may also comprise a liquid material that is converted to a solid by exposure to heat, by exposure to ultraviolet light, and/or by a chemical reaction within the material (e.g., a thermosetting material). As shown in FIG. 14, the cavity blocks 310 and 312′ are retracted from one another to provide an intermediate premolded substrate that has solidified molding material 330′ formed between the surfaces of the leadframes and between the leads of the leadframes, without electrical components disposed on the leadframes, and without apertures 35 present. The top cavity block 312′ may be coated with a material layer that does not adhere to the molding material. (As another approach, a doctor-blade deposition process may be used to squeegee liquid molding material between the surfaces of the leadframe.) Next, referring to FIG. 15, the intermediate premolded substrates are passed through a stamp cutter having a cutter blade assembly 412 and a support base 410. The cutter blade assembly 412 has blades 414 that form apertures 35 in the initial premolded substrates when the assembly 412 and support base 410 are brought together in a stamping operation. Support base 410 supports the initial premolded leadframes during the stamping operation, and provides passages 411 through which cuttings 333 may pass through.

In the above illustrated embodiments, the ends of the formed apertures 35 are free of leads of the leadframe, and the leads do not extend into or over the apertures.

It should be understood that where the performance of an action of any of the methods disclosed and claimed herein is not predicated on the completion of another action, the actions may be performed in any time sequence (e.g., time order) with respect to one another, including simultaneous performance and interleaved performance of various actions. (Interleaved performance may, for example, occur when parts of two or more actions are performed in a mixed fashion.) Accordingly, it may be appreciated that, while the method claims of the present application recite sets of actions, the method claims are not limited to the order of the actions listed in the claim language, but instead cover all of the above possible orderings, including simultaneous and interleaving performance of actions and other possible orderings not explicitly described above, unless otherwise specified by the claim language (such as by explicitly stating that one action precedes or follows another action).

The premolded substrate, die packages, and optocoupler packages described above can be used in electrical assemblies including circuit boards with the packages mounted thereon. They may also be used in systems such as phones, computers, etc. It may be appreciated that more than additional semiconductor dice may be assembled with each package to provide greater functionality and circuit density.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. A premolded substrate for semiconductor die packages, said pre-molded substrate comprising:
a leadframe having a first surface, a second surface, a central portion disposed between the first and second surfaces, and a plurality of electrically conductive leads disposed about the central portion;
a body of electrically insulating material disposed in a portion of the central portion of the leadframe and between the leads of the leadframe; and
an aperture disposed in the leadframe's central portion and between the leadframe's first and second surfaces.

2. The premolded substrate of claim 1, wherein the leadframe has a thickness in the range of 50 microns to 500 microns.

3. The premolded substrate of claim 1, wherein the leadframe has a thickness in the range of 100 microns to 250 microns.

4. The premolded substrate of claim 1, wherein the body of electrically insulating material comprises an epoxy molding material, a polyimide, or a silicone.

5. The premolded substrate of claim 1, wherein the aperture has a dimension that is equal to or greater than 0.5 mm.

6. The premolded substrate of claim 1, wherein the aperture has dimensions that are equal to or less than 2.5 cm.

7. The premolded substrate of claim 1, wherein the aperture is a first aperture, and wherein the premolded substrate further comprises a second aperture disposed in the leadframe's central portion adjacent to the first aperture and between the leadframe's first and second surfaces.

8. The premolded substrate of claim 7, wherein the leadframe further comprises at least one lead disposed between the first and second apertures.

9. The premolded substrate of claim 1, wherein at least one lead of the leadframe has an interior end that abuts a portion of the perimeter of the aperture.

10. The premolded substrate of claim 1, wherein the leadframe has a thickness between its first and second surfaces, and wherein at least one lead of the leadframe has an interior end that has a thickness that is less than half the thickness of the leadframe.

11. A semiconductor die package comprising:
the premolded substrate according to claim 1;
a first semiconductor die disposed over the aperture; and
a second semiconductor die disposed within the aperture.

12. The semiconductor die package of claim 11, wherein the second semiconductor die is attached to the first semiconductor die.

13. A semiconductor die package comprising:
the premolded substrate according to claim 1;
a first semiconductor die disposed over the aperture at the first surface of the leadframe; and
a second semiconductor die disposed over the aperture at the second surface of the leadframe.

14. A method of making a premolded substrate for semiconductor die packages, said method comprising:
forming a body of molding material between the surfaces of a leadframe with an aperture passing between the surfaces of the leadframe, and without any electrical components attached to the leadframe.

15. The method of claim 14 wherein forming the body of molding material comprises allowing a body of liquid molding material to solidify to a solid state with a protrusion of a molding tool disposed in the location of the aperture.

16. The method of claim 14 wherein forming the body of molding material comprises disposing a body of liquid molding material in the space between a leadframe and a protrusion of a molding tool, the protrusion being disposed in the location of the aperture; and
thereafter allowing the body of liquid molding material to solidify to a solid state.

17. The method of claim 14, wherein forming the body of molding material comprises forming a body of solid molding material between the surfaces of the leadframe and among the leads of the leadframe; and
thereafter removing portion of the body of solid molding material to provide at least one aperture passing between the surfaces of the leadframe.
